(19) United States
(12) Patent Application Publication
(10) Pub. No.: US 2024/0427231 A1
(43) Pub. Date: Dec. 26, 2024

(54) OPTICAL PROXIMITY CORRECTION METHOD AND MASK MANUFACTURING METHOD BY USING THE SAME

(71) Applicant: Samsung Electronics Co., Ltd., Suwon-si (KR)

(72) Inventor: Byungje JUNG, Suwon-si (KR)

(73) Assignee: Samsung Electronics Co., Ltd., Suwon-si (KR)

(21) Appl. No.: 18/417,593

(22) Filed: Jan. 19, 2024

(30) Foreign Application Priority Data
Jun. 26, 2023 (KR) 10-2023-0082187

(51) Int. Cl. G03F 1/36

(52) U.S. Cl. CPC G03F 1/36

(57) ABSTRACT

The inventive concepts provide an optical proximity correction (OPC) method capable of implementing a pattern having a critical pitch by using a single exposure patterning, and a mask manufacturing method including the OPC method. The OPC method includes receiving a design layout for a target pattern to be formed on a substrate, obtaining an OPC pattern by performing a first OPC on the design layout, obtaining a simulation contour of the OPC pattern, based on the simulation contour of the OPC pattern, performing a line-end sharpening (LES) OPC on line-ends of line patterns extending in a first direction and adjacent to each other in the first direction, cutting a portion of the line-end of the line pattern, and performing a second OPC on side lines of another line pattern adjacent to the line-end in a second direction perpendicular to the first direction and extending in the first direction.

### CROSS-REFERENCE TO RELATED APPLICATION

This application is based on and claims priority under 35 U.S.C. § 119 to Korean Patent Application No. 10-2023-0082187, filed on Jun. 26, 2023 in the Korean Intellectual Property office, the disclosure of which is incorporated by reference herein in its entirety.

### BACKGROUND

The inventive concepts relate to a method of manufacturing a mask, and in particular, to an optical proximity correction (OPC) method and a mask manufacturing method using the OPC method.

In a semiconductor process, a photolithography process using a mask may be performed to form a pattern on a semiconductor substrate such as a wafer. The mask may be simply defined as a pattern transfer body in which a pattern shape of an opaque material is formed on a transparent base material. A manufacturing process of the mask is briefly described. First, a required circuit may be designed and a layout of the circuit may be designed. Then, design data obtained by using an OPC method may be transferred as mask tape-out (MTO) design data.

Next, a mask data preparation (MDP) operation may be performed based on the MTO design data, and an exposure process or the like may be performed on a mask substrate.

### SUMMARY

The inventive concepts provide an optical proximity correction (OPC) method enabling the implementation of a pattern having a critical pitch by using a single exposure patterning, and a mask manufacturing method including the OPC method.

In addition, the issues to be solved by the technical idea of the inventive concepts are not limited to those mentioned above, and other issues may be clearly understood by those of ordinary skill in the art from the following descriptions.

According to an aspect of the inventive concepts, there is provided an optical proximity correction (OPC) method including receiving a design layout for a target pattern to be formed on a substrate, obtaining an OPC pattern by performing a first OPC on the design layout, obtaining a simulation contour of the OPC pattern, performing, based on the simulation contour, a line-end sharpening (LES) OPC on line-ends of line patterns included in the OPC pattern, the line patterns extending in a first direction and adjacent to each other in the first direction, cutting a portion of at least one of the line-ends of the line pattern, and performing a second OPC on side lines of another line pattern, the another line pattern adjacent to the at least one line-end in a second direction perpendicular to the first direction and extending in the first direction.

In addition, according to another aspect of the inventive concepts, there is provided an optical proximity correction (OPC) method including receiving a design layout for a target pattern to be formed on a substrate, obtaining an OPC pattern by performing a first OPC on the design layout, obtaining a simulation contour of the OPC pattern, defining, based on the simulation contour, a reference bridge margin region and a bulging bridge margin region for line-ends of line patterns included in the OPC pattern, the line patterns extending in the first direction and being adjacent to each other in the first direction, performing a line-end sharpening (LES) OPC on at least one of the line-ends such that an overlap region, in which another line pattern adjacent to the at least one line-end in a second direction perpendicular to the first direction and extending in the first direction overlaps the bulging bridge margin region, is removed, cutting a portion of the at least one line-end, and performing a second OPC on a side line of the other line pattern, wherein, when the target pattern uses only the first OPC and comprises a critical line width which would otherwise require two times or more of an extreme ultra-violet (EUV) exposure process, the target pattern is formed using the EUV exposure process once.

Furthermore, according to another aspect of the inventive concepts, there is provided a mask manufacturing method including performing an optical proximity correction (OPC) method such that an OPCed design layout is obtained, the OPCed design corresponding to a target pattern to be formed on a substrate, preparing mask tape-out (MTO) design data, the MTO design data based on the OPCed design layout data, preparing mask data based on the MTO design data, and
performing exposure onto a mask substrate based on the mask data, wherein the performing of the OPC method includes receiving a design layout for a target pattern to be formed on a substrate, obtaining an OPC pattern by performing a first OPC on the design layout, obtaining a simulation contour of the OPC pattern, performing, based on the simulation contour, a line-end sharpening (LES) OPC on line-ends of line patterns included in the OPC pattern, the line patterns extending in a first direction and adjacent to each other in the first direction, cutting a portion of at least one of the line-ends, and performing a second OPC on side lines of another line pattern, the another line pattern adjacent to the at least one line-end in a second direction perpendicular to the first direction and extending in the first direction.

### BRIEF DESCRIPTION OF THE DRAWINGS

Embodiments will be more clearly understood from the following detailed description taken in conjunction with the accompanying drawings in which:

FIG. 1 is a schematic flowchart of a process of an optical proximity correction (OPC) method, according to at least one embodiment;

FIG. 2 is a detailed flowchart of performing a line-end sharpening (LES) OPC in the OPC method in FIG. 1;

FIG. 3 is a conceptual diagram illustrating a target pattern and an OPC pattern as a first OPC result, in a process of obtaining the OPC pattern of the OPC method of FIG. 1;

FIGS. 4A through 4C are conceptual diagrams and a scanning electron microscope (SEM) photograph for explaining a process of defining reference bridge margin regions and bulging bridge margin regions, in an operation of performing the LES OPC of FIG. 2;

FIGS. 5A through 5D are conceptual diagrams and SEM photographs for explaining a process of thinning portions of the OPC pattern corresponding to line-ends, in the operation of performing the LES OPC of FIG. 2;

FIGS. 6A and 6B are conceptual diagrams for explaining a process of cutting portions of the line-ends, in the OPC method of FIG. 1;

FIGS. 7A and 7B are conceptual diagrams for explaining a process of performing a second OPC on a side line of a different line pattern, in the OPC method of FIG. 1;

FIGS. 8A through 8C are SEM photographs of line patterns having critical pitches, and conceptual diagrams for explaining a single exposure patterning and a double exposure patterning;

FIGS. 9A through 9C are conceptual diagrams of a design layout of a target pattern, an OPC pattern of a comparison example by using the OPC method, and an OPC pattern of the present embodiment by using the OPC method, respectively; and

FIG. 10 is a schematic flowchart of a mask manufacturing method including an OPC method, according to at least one embodiment.

### DETAILED DESCRIPTION OF THE EMBODIMENTS

Hereinafter, embodiments of the inventive concepts will be described in detail with reference to the accompanying drawings. Identical reference numerals are used for the same constituent elements in the drawings, and duplicate descriptions thereof are omitted.

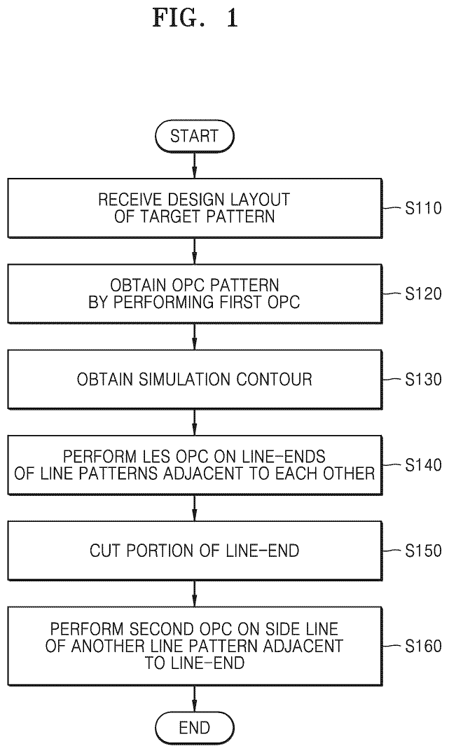

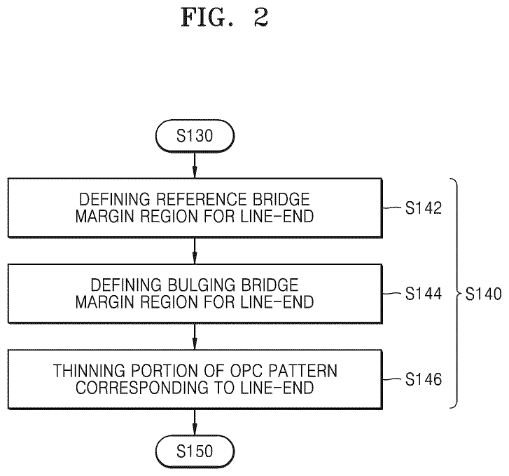

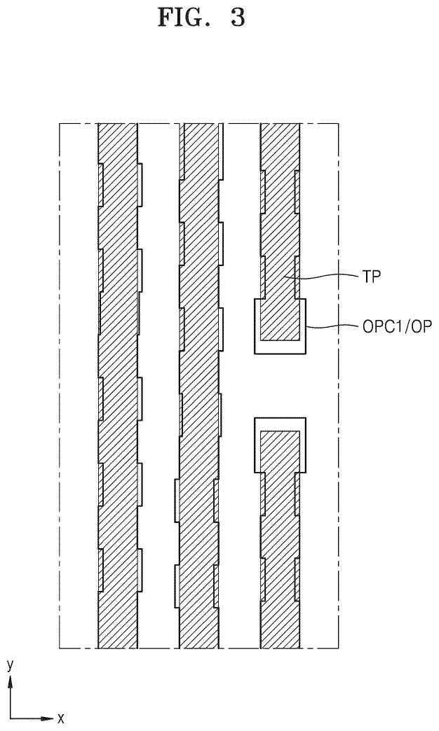

FIG. 1 is a schematic flowchart of a process of an optical proximity correction (OPC) method, according to at least one embodiment, and FIG. 2 is a detailed flowchart of performing a line-end sharpening (LES) OPC in the OPC method in FIG. 1. FIGS. 3 through 7B are conceptual diagrams and scanning electron microscope (SEM) photographs for explaining operations of the OPC method of FIG. 1.

Referring to FIG. 1, in the OPC method of the present embodiment, a design layout of a target pattern to be formed on a substrate is received (S110). In this case, the target pattern represents a pattern to be formed on a substrate (e.g., silicon (Si) substrate such as a wafer). For example, the target pattern may be a pattern to be formed on a substrate by transferring a pattern on a mask onto a substrate using an exposure process. On the other hand, because the pattern on the mask is reduced, projected and transferred onto the wafer, the pattern on the mask may have a larger size than the target pattern on the substrate.

The design layout represents a layout for the pattern on the mask corresponding to the target pattern. Due to exposure process characteristics, the target pattern on the wafer may have a different shape from that of a pattern on a real mask used in the exposure process. However, in at least some embodiments, the shape of an initial design layout for the pattern on the mask may be substantially the same as the pattern of the target pattern.

On the other hand, in the OPC method of the present embodiment, the target pattern may have a line & space shape. In the line & space shape of the target pattern, edges may include only lines. Accordingly, the design layout for the target pattern of the line&space shape may correspond to a rectangular design layout. For reference, in the OPC method of the present embodiment, the target pattern may correspond to, for example, an after cleaning inspection target pattern.

After the design layout is received, the OPC pattern is obtained by performing a first OPC on the design layout (S120). The first OPC may correspond to, for example, a baseline OPC. The baseline OPC may mean a general OPC for implementing a patterning close to the target pattern on a substrate. For reference, the OPC may mean a method in which as the pattern becomes finer, an optical proximity effect (OPE) due to influence between adjacent patterns is generated during the exposure process, and to overcome this issue, an occurrence of the OPE is suppressed by correcting the design layout of the pattern on the mask.

In the case of the target pattern of a line & space shape, an OPC pattern (refer to OPC1/OP in FIG. 3) as the result of the first OPC (that is, baseline OPC) for the design layout may include a hammer head shape and a jog shape. In the OPC pattern OPC1/OP after the first OPC, a line-end of a line pattern may have a hammer head shape, and side lines of the line pattern may be divided into small segments to have a jog shape. For reference, a segment may be referred to as a fragment, and may mean a line of a straight line shape corresponding to an edge of the design layout, or data for the line. The edge of the design layout may be divided into a plurality of segments according to a certain division rule. A length of the segment, the division rule, or the like may be set by a user performing the OPC method.

FIG. 3 is a conceptual diagram illustrating the target pattern of a line & space shape and the OPC pattern OPC1/OP after the first OPC, in a process of obtaining the OPC pattern of the OPC method of FIG. 1. In FIG. 3, a hatched portion may correspond to a target pattern TP of a line & space shape, or the design layout corresponding to the target pattern TP (hereinafter, ‘target pattern’). The target pattern TP may include, for example, four line patterns, and on the right side, two line-ends of line patterns adjacent to each other are illustrated in a y direction. On the other hand, straight lines on the periphery surrounding the target pattern TP may correspond to segments of the OPC pattern OPC1/OP. In addition, as described above, segments may be arranged in a jog shape on side lines of the line pattern, and the segments may have a hammer head shape at the line-ends of the line pattern.

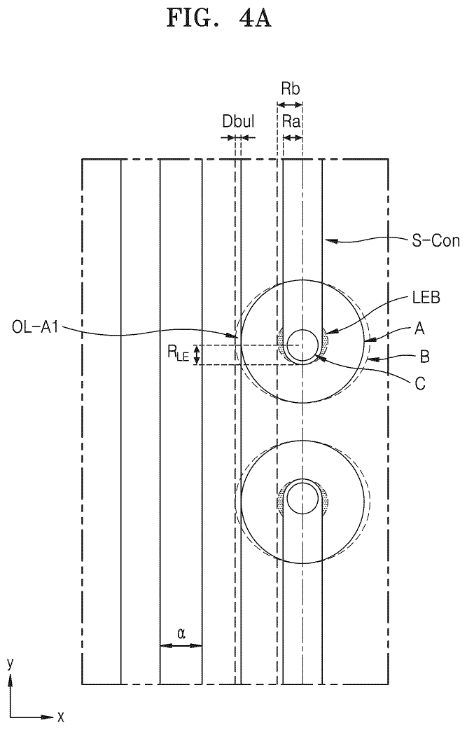

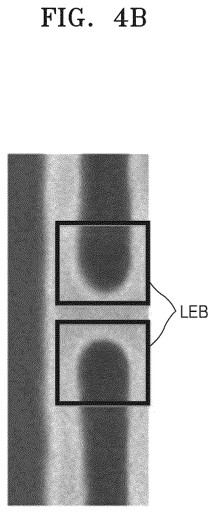

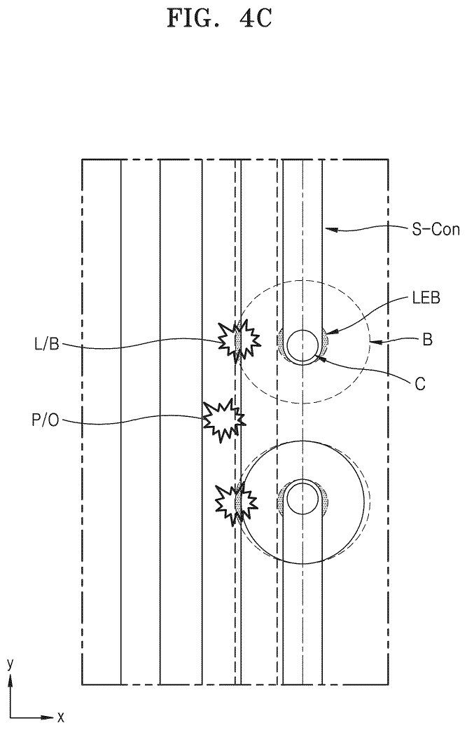

After the OPC pattern OPC1/OP through the first OPC is obtained, a simulation contour (refer to S-Con in FIG. 4A) for the OPC pattern OPC1/OP is obtained (S130). For example, data for the OPC pattern OPC1/OP may be input into an OPC model and a contour may be extracted by using a simulation. For reference, in the OPC model, various baseline data may be input as input data. In this case, the baseline data may include data of the OPC pattern OPC1/OP. In addition, the baseline data may include information data of thickness, refractive index, dielectric constant, or the like of a photoresist (PR), and pieces of data of a source map for a type of an illumination system. However, the baseline data is not limited thereto. As a result, the simulation contour S-Con may, as a resultant product generated by a simulation using the OPC model, correspond to a shape of the target pattern TP formed on the wafer, in the exposure process using a mask. Accordingly, the purpose of the OPC method may be to make the simulation contour S-con as similar as possible to the shape of the target pattern TP.

After the simulation contour S-Con is obtained, based on the simulation contour S-Con, the line-end sharpening (LES) OPC is performed at the line-ends of the line patterns adjacent to each other (S140).

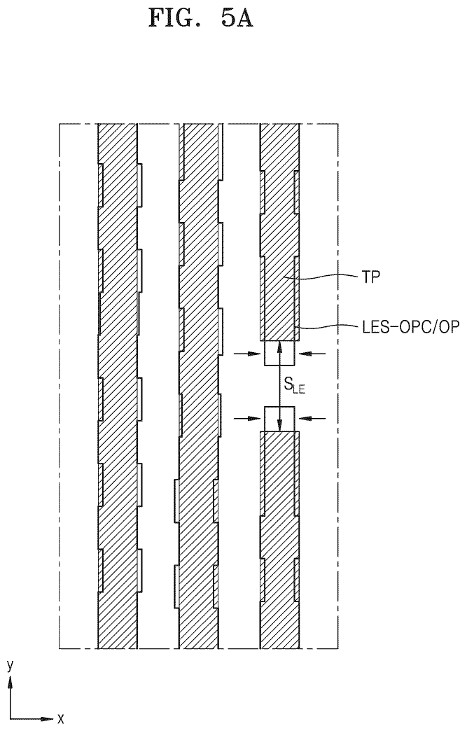

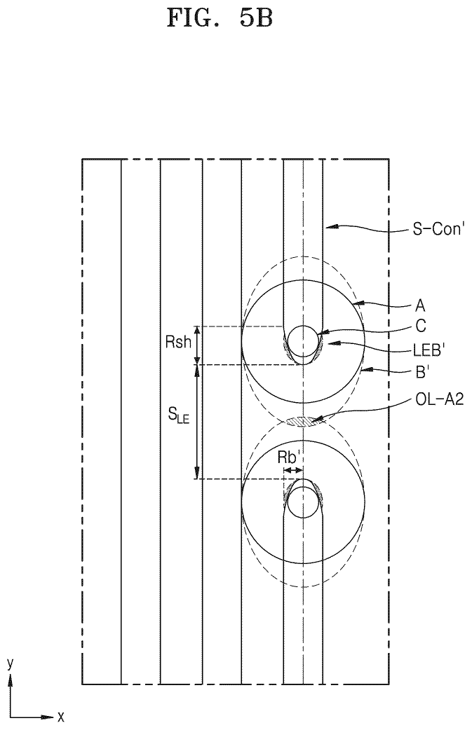

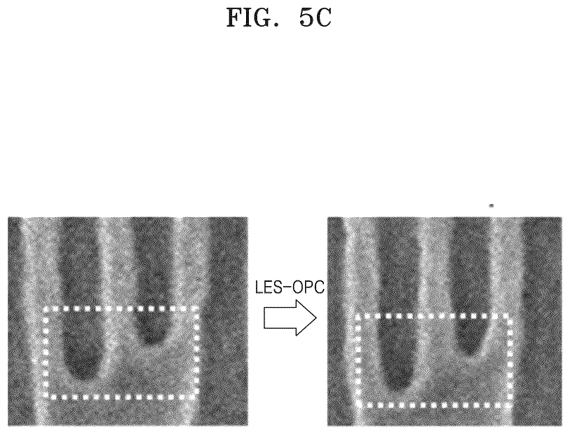

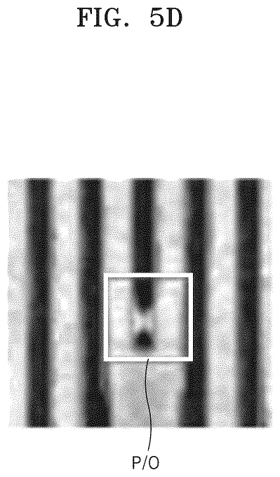

FIGS. 4A through 4C are conceptual diagrams and an SEM photograph for explaining a process of defining reference bridge margin regions and bulging bridge margin regions, in an operation of performing the LES OPC of FIG. 2, and FIGS. 5A through 5D are conceptual diagrams and SEM photographs for explaining a process of thinning portions of the OPC pattern corresponding to line-ends, in the operation of performing the LES OPC of FIG. 2. Hereinafter, referring to FIGS. 2 and 4A through 5D, operations of performing the LES OPC are described in detail.

Referring to FIGS. 2 and 4A through 4C, the operation of performing the LES OPC (S140) may first define a reference bridge margin region A for the line-end of a line pattern (S142). The reference bridge margin region A may be defined based on a reference radius Ra. The reference radius Ra may correspond to ½ of a width of a line pattern in a first direction (e.g., the x direction). In addition, the reference bridge margin region A may be defined as a region covered by the reference radius Ra plus a process margin at the line-end. In this case, the process margin may include the distance in the x direction between line patterns adjacent to each other in the x direction. For example, when the distance between the line patterns in the x-direction is defined as a, the reference bridge margin region A may be defined in the form of a circle with a radius of Ra+α at the line-end.

Additionally, a line-end radius R_{LE} may be defined at the line-end. The line-end radius R_{LE} may be defined as the distance from the point, where the side line of the line pattern extending in a second direction (e.g., the y direction) changes from a straight line to a curved shape, to the line-end of the line pattern in the y direction. When the simulation contour S-con is obtained as a semi-circle at the line-end portion, the reference radius Ra may be the same as the line-end radius R_{LE}, however the examples are not limited thereto.

Next, a bulging bridge margin region B of the line-end of the line pattern may be defined (S144). The bulging bridge margin region B may be defined based on a bulging radius Rb or a bulging LEB. The bulging radius Rb may correspond to ½ of the maximum width in the x direction corresponding to the bulging LEB of the line-end. In addition, the bulging bridge margin region B may be defined as a region covered by the bulging LEB plus a process margin at the line-end. For example, when the process margin is α, the bulging bridge margin region B may be defined in a shape covered by the bulging LEB plus α. In FIG. 4A, as the bulging LEB is formed convex at a semicircular portion by the line-end radius R_{LE} in both directions of the x direction, the bulging bridge margin region B may be defined in an elliptical shape long in the x direction. Additionally, according to at least one embodiment, the bulging bridge margin region B may also be defined as a region covered by the bulging radius Rb plus the process margin. In this case, the bulging bridge margin region B may appear in a round and/or circular shape.

A first overlap region OL-A1 may be generated by the bulging bridge margin region B. The first overlap region OL-A1 may mean a region where a line pattern adjacent to the bulging bridge margin region B in the x direction overlaps the bulging bridge margin region B. When a width of the first overlap region OL-A1 in the x direction is defined as Dbul, the Dbul may be calculated by using Formula 1 below.

Dbul=Rb−Ra [Formula 1]

Both Ra and Rb may correspond to a reference radius and a bulging radius defined above, respectively. The reason why Dbul is calculated by using Formula 1 may be, as understood with reference to FIG. 4A, which illustrates that the bulging bridge margin region B is defined by combining Rb with α, which is a process margin, when a circle, in which a is added to Ra, contacts an adjacent line pattern, the width, in which the bulging bridge margin region B overlaps a line pattern adjacent to the bulging bridge margin region B in the x direction, may be calculated as Rb−Ra.

For reference, the bulging LEB may represent a shape, in which both ends of the line-ends of the line patterns are convex outwardly, in an etching process of a substrate. The SEM photograph of FIG. 4B shows that a line-end bulging LEB at the line-end occurs at line-ends of the line patterns. The line-end bulging LEB at the line-end may cause, as illustrated in FIG. 4C, a line bridge L/B defect between the adjacent line patterns. In addition, the line-end bulging LEB may cause a pinch-off (P/O) defect on another adjacent line pattern. For reference, because a line is generally formed of copper (Cu), the line bridge L/B may also be referred to as a Cu bridge. Additionally, although a cause of the pinch-off P/O defect of another adjacent line pattern at the line-end is set aside, it may be easily understood that the line bridge L/B defect at the line-end portions of the adjacent line patterns is caused by the first overlap region OL-A1 between the bulging bridge margin region B and the other adjacent line pattern.

Referring to FIGS. 2 and 5A through 5D, after the bulging bridge margin region B is defined, a portion of the OPC pattern corresponding to the line-end is thinned (S146). As illustrated in FIG. 5A, OPC pattern LES-OPC/OP of a line-end in line patterns adjacent to each other in a y direction may be formed thin and long. Two pairs of arrows facing each other at each of the line-ends may indicate that the OPC pattern LES-OPC/OP is thinner than the OPC pattern OPC1/OP in FIG. 3.

When the OPC pattern LES-OPC/OP of the line-end becomes thin and long, as illustrated in FIG. 5B, a line-end radius Rsh of a simulation contour S-Con′ may correspondingly increase. For example, the line-end radius R_{LE} before a LES-OPC may be changed to the line-end radius Rsh after the LES-OPC, and the line-end radius Rsh may be greater than the line-end radius R_{LE}. As a result, the LES-OPC may correspond to a process of intentionally increasing a line-end radius, removing the hammer head of the OPC pattern of the line-end, and thinning a shape of the line-end. The SEM photographs in FIG. 5C show actually thinner and longer shapes of the line-end of the line pattern by using the LES-OPC.

When the line-end radius R_{LE} is changed to the line-end radius Rsh by using the LES-OPC, a shape of a bulging LEB′ may be changed, and accordingly, a bulging bridge margin region B′ may be changed. The bulging bridge margin region B′ is illustrated as a dashed line in FIG. 5B. As described above, the bulging bridge margin region B′ may be defined based on the bulging LEB′ or a bulging radius Rb′. For example, the bulging radius Rb′ may correspond to ½ of the maximum width in the x direction corresponding to the bulging LES' of the line-end. In addition, the bulging bridge margin region B′ may be defined as a region covered by the bulging LES' or the bulging radius Rb′ plus a process margin at the line-end. Additionally, the LES-OPC may be performed so that the bulging radius Rb′ satisfies Formula 2 below.

Rc≤Rb′≤Ra [Formula 2]

In Formula 2, the bulging radius Rb′ is less than or equal to the reference radius Ra. For example, when the bulging radius Rb′ exceeds the reference radius Ra, the bulging bridge margin region B′ may overlap a line pattern adjacent thereto in the x direction. On the other hand, a radius Re may correspond to a minimum radius at the line-end so that the pinch-off P/O defect does not occur at the line-end portion. In FIGS. 4A and 5B, the radius Rc is not shown, a circle C defined by the radius Rc at the line-end is illustrated. The SEM photograph of FIG. 5D shows the pinch-off P/O defect that occurs as the bulging radius Rb′ is formed smaller than the radius Rc.

Additionally, as the OPC pattern LES-OPC/OP of the line-end becomes thin and long at the line-end, the bulging LES' may also become long in the y direction, and accordingly, the bulging bridge margin region B′ may also increase in the y direction. Accordingly, as illustrated in FIG. 5B, the bulging bridge margin regions B′ at the line-ends of the line patterns adjacent to each other in the y direction may overlap each other to generate a second overlap region OL-A2. Accordingly, a process of preventing generation of the second overlap region OL-A2 may be performed.

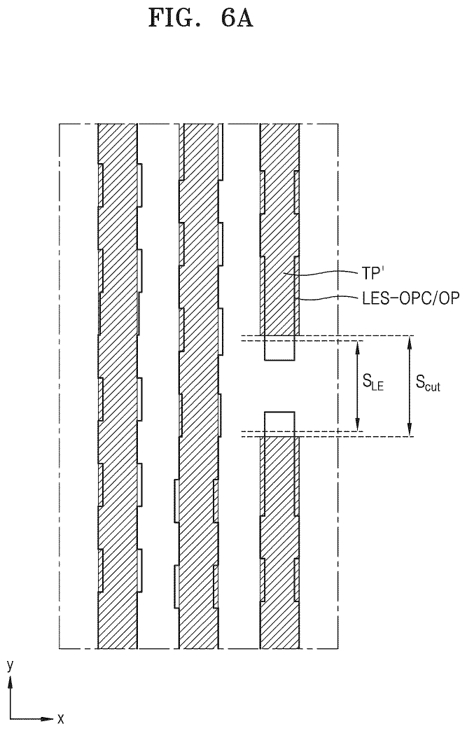

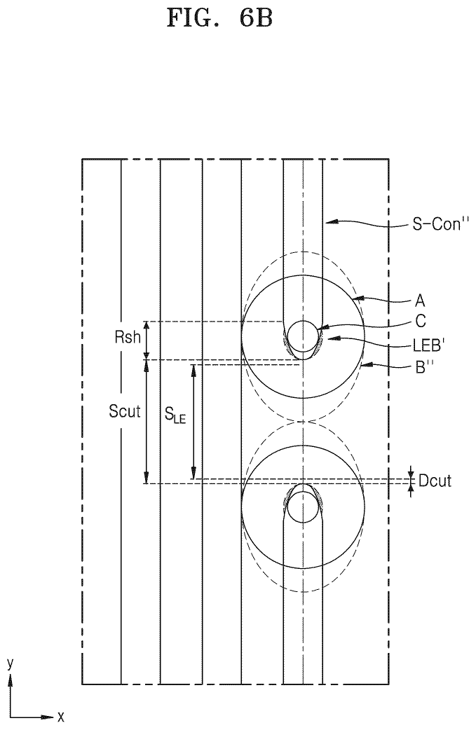

FIGS. 6A and 6B are conceptual diagrams for explaining a process of cutting portions of the line-ends, in the OPC method of FIG. 1.

Referring to FIGS. 1, 6A, and 6B, after the LES OPC, portions of the line-ends are cut (S150). To cut portions of the line-ends, firstly, the distance S_{LE} between adjacent line-ends in the target pattern TP, and the distance Scut between adjacent line-ends in the target pattern TP′ after cutting may be defined. The distance S_{LE} is illustrated on the target patterns TP and TP′ in FIGS. 5A and 6A, respectively. In addition, the distance Scut is illustrated on the target pattern TP′ in FIG. 6A. On the other hand, the distances S_{LE} and Scut may also be defined by simulation contours S-Con′ and S-Con″. For example, the distance S_{LE} may be defined as a distance between adjacent line-ends of a simulation contour, and the distance Scut may be defined as a distance between adjacent line-ends of the simulation contour after cutting. The distance S_{LE} is illustrated on the simulation contours S-Con′ and S-Con″ in FIGS. 5B and 6B, respectively. In addition, the distance Scut is illustrated on the simulation contour S-Con″ in FIG. 6B.

When a width to be cut at a line-end of each of adjacent line patterns is defined as a width Dcut, the width Dcut may be calculated by using Formula 3 based on the definition of the distances S_{LE} and Scut.

Dcut=(Scut−S_{LE})/2 [Formula 3]

With reference to FIG. 5B, it may be understood that the width Dcut corresponds to ½ of the width of the second overlap region OL-A2. For example, the difference between the distance Scut and the distance S_{LE} may correspond to a maximum width in the y direction of the second overlap region OL-A2. Accordingly, a width to be cut at the line-end of each of the adjacent line patterns may be ½ of the maximum width, or the width Dcut. Thus, Formula 3 may hold true. As a result, by removing the line-end of each of the line patterns by the width Dcut, the second overlap region OL-A2 may be removed. For example, the bulging bridge margin regions B′ at the line-ends of the adjacent line patterns in the y direction may not overlap each other.

Additionally, cutting the line-end of the line pattern may correspond to changing the shape of the target pattern in the end. For example, the OPC method of the present embodiments may perform modification on the target pattern, through which the target pattern to be formed on the substrate is slightly changed.

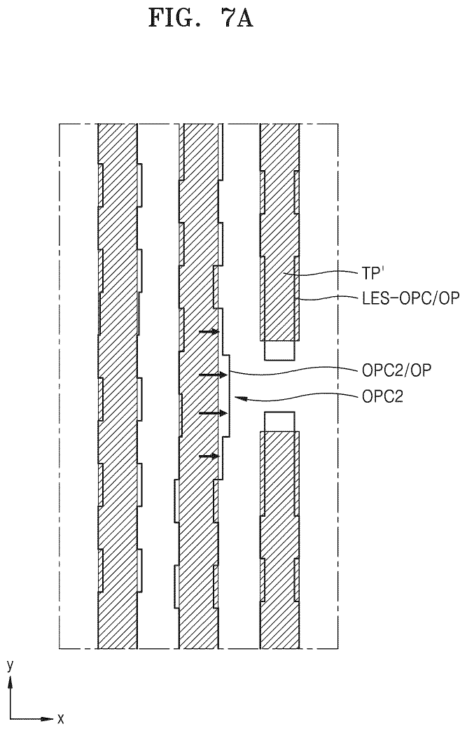

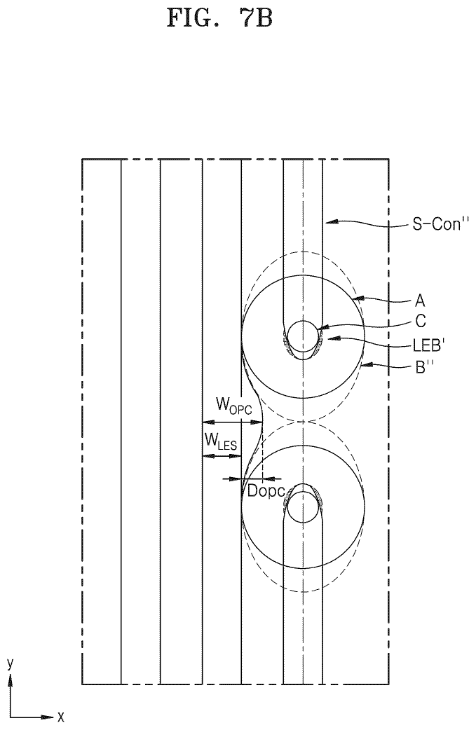

FIGS. 7A and 7B are conceptual diagrams for explaining a process of performing a second OPC on a side line of a different line pattern, in the OPC method of FIG. 1.

Referring to FIGS. 7A and 7B, after portions of the line-ends are cut, a second OPC OPC2 is performed on the side line of the other line pattern adjacent to the line-ends (S160). As described above, the Pinch-off P/O defect may occur in another line pattern adjacent to the line-ends in the x direction. To prevent the pinch-off P/O defect, a portion, where the pinch-off P/O defect of other line pattern occurs, may need to be formed thick. Accordingly, in the OPC method of the present embodiments, the second OPC OPC2 may be performed to move the side line of another line pattern adjacent to the line-ends in the x direction and make a corresponding portion of the other line pattern thick.

As may be understood with reference to the arrows in FIG. 7A, in an OPC pattern OPC2/OP obtained by using the second OPC OPC2, the OPC pattern OPC2/OP adjacent to the line-ends may move toward the line-ends, and thus, it may be identified that the corresponding portion of the other line pattern is thickening. On the other hand, as may be understood with reference to FIG. 7B, in a simulation contour based on the OPC pattern OPC2/OP, a simulation contour portion of the corresponding portion of the other line pattern may be required not to overlap simulation contour portions of the line-ends.

Accordingly, when a width of a side line portion of the other line pattern in the x after the second OPC OPC2 is defined as a width Wopc, and a width of the side line portion of the other line pattern in the x direction before the second OPC OPC2 is defined as a width W_{LES}, to prevent the pinch-off P/O defect, an increased width Dope defined by Formula 4 may be increased and/or maximized.

Dopc=Wopc−W_{LES} [Formula 4]

In Formula 4, the increased width Dope may correspond to an increased width of the side line of the other line pattern, which has been increased by the second OPC OPC2. Accordingly, to prevent the pinch-off P/O defect, the increased width Dopc, which is an increased width of the side line of the other line pattern, may be increased and/or maximized. On the other hand, the increased width Dope may vary depending on a size of a segment in a segment division on the side line of the other line pattern. For example, as the size of the segment decreases, the increased width Dope may increase.

The OPC method of the present embodiments may include a process of LES OPC to thin out an OPC pattern of line-end portions of line patterns adjacent to each other in the y direction, a process of cutting a portion of the line-end of each of the line patterns, and a process of performing the second OPC OPC2 on another line pattern adjacent to line-ends in the x direction. Accordingly, the OPC method of the present embodiments may sufficiently secure a mass production margin for the target pattern. The OPC method of the present embodiments may provide a method to sufficiently secure a pinch-off P/O margin and a line bridge L/B, in comparison with a general OPC, for example, the first OPC, with respect to the target pattern having the critical pitch, and in addition, the pinch-off P/O margin in another line pattern adjacent to the line-ends. As a result, the OPC method of the present embodiments may provide a method in which the target pattern having the critical pitch is implemented by using the single exposure patterning, and particularly, the target pattern having the critical pitch is implemented by using a single exposure patterning in an extreme ultra-violet (EUV) process. On the other hand, as described above, the OPC method of the present embodiments may include a process of modifying the target pattern by using a process of cutting a portion of the line-end of each of the line patterns.

For reference, in the case of patterns having the critical pitch in the EUV process, due to a limit in a semiconductor process, it may be difficult, and/or impossible, to secure a mass production margin with no defects, such as the pinch-off P/O and the bridge. Accordingly, to the patterns having the critical pitch in the EUV process, in general, by applying a double exposure patterning process or a double patterning process, a mass production margin and a yield may be secured. Based on a manufacturing process, the double patterning process may also be referred to as a litho-etching-litho-etching (LELE) process. In addition, to form patterns having the critical pitch, a triple patterning or a quadruple patterning may also be used in addition to a double patterning. However, when the double patterning process is used, because the number of masks and the number of exposure processes increase correspondingly, the double patterning process may be disadvantageous from aspects of cost and time. On the other hand, the OPC method of the present embodiments may, as described above, provide a method in which, by sufficiently securing a pinch-off P/O margin, a bridge margin, or the like for the target pattern having the critical pitch, the target pattern having the critical pitch is implemented by using a single exposure patterning or a single patterning process. In addition, that “the OPC method secures a margin” may substantially have the same meaning as that “the OPC method provides a method of manufacturing a mask capable of securing a margin”.

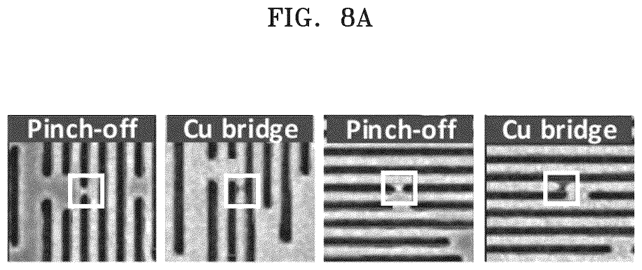

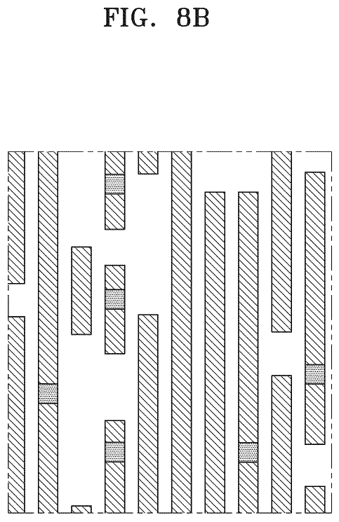

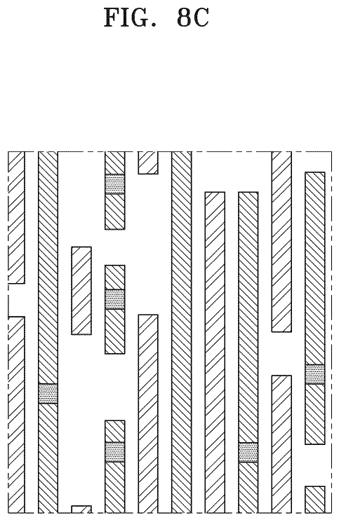

FIGS. 8A through 8C are SEM photographs of line patterns having critical pitches, and conceptual diagrams for explaining the single exposure patterning and the double exposure patterning.

Referring to FIGS. 8A through 8C, the SEM photographs in FIG. 8A show defects occurring in the single exposure patterning process using EUV, with respect to the line patterns having the critical pitch. The leftmost and second leftmost SEM photographs show the defects of the pinch-off P/O and the Cu bridge in the line patterns extending in the y direction, respectively. In addition, the second rightmost and rightmost SEM photographs show the defects of the pinch-off P/O and the Cu bridge in the line patterns extending in the x direction, respectively.

It may be identified that the defects of the pinch-offs P/O occur at line-ends of the line patterns. It may be identified that the pinch-off P/O defect of the leftmost SEM photograph occurs in a line pattern adjacent to the right side of the two line patterns adjacent to each other in the y direction, and the Cu bridge defect of the leftmost second SEM photograph occurs in line-end of a lower line pattern of the two line patterns adjacent to each other in the y direction. It may be identified that the pinch-off P/O defect of the rightmost second SEM photograph occurs in a line pattern adjacent to the upper side of the two line patterns adjacent to each other in the x direction, and the Cu bridge defect of the rightmost SEM photograph occurs in line-end of a left line pattern of the two line patterns adjacent to each other in the x direction.

FIG. 8B illustrates a shape, in which line patterns having the critical pitch are formed by using the single exposure patterning process, and FIG. 8C illustrates a shape in which line patterns having the critical pitch are formed by using the double exposure patterning process. To distinguish between the single exposure patterning process and the double exposure patterning process, line patterns are illustrated in the same hatching in FIG. 8B, and in two hatchings in FIG. 8C. For example, the single exposure patterning process may mean a process of forming the entire line patterns in one mask, and forming the entire line patterns by using an exposure process once. On the other hand, the double exposure patterning process may mean a process of dividing line patterns into two masks, performing an exposure process per mask once, and forming the entire line patterns by using a total of two exposure processes.

In FIGS. 8B and 8C, squares are illustrated in some line patterns, and such squares may correspond to portions where defects occur. For example, in the case of the single exposure patterning process, a pinch-off P/O defect and/or a line bridge L/B defect may occur in the squares. On the other hand, although not completely excluded, in the case of the double exposure patterning process, defects may not occur in the squares.

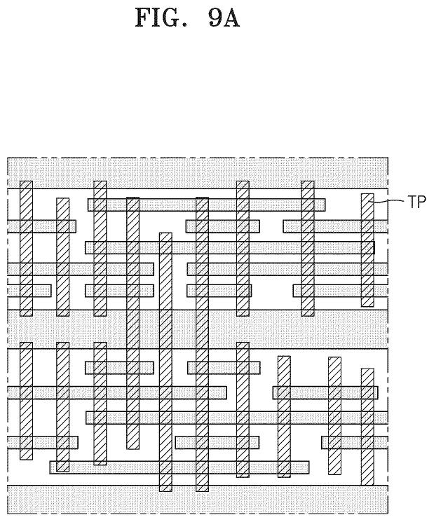

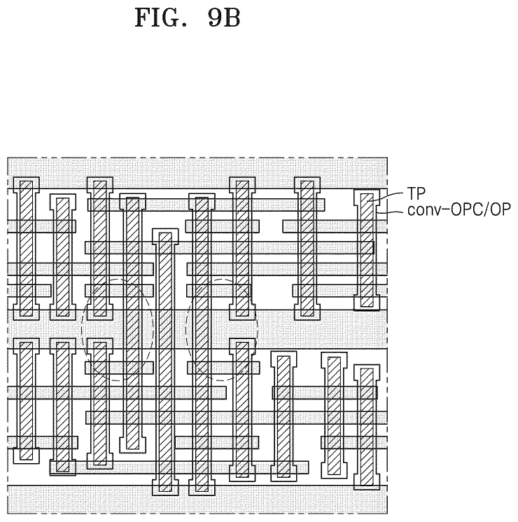

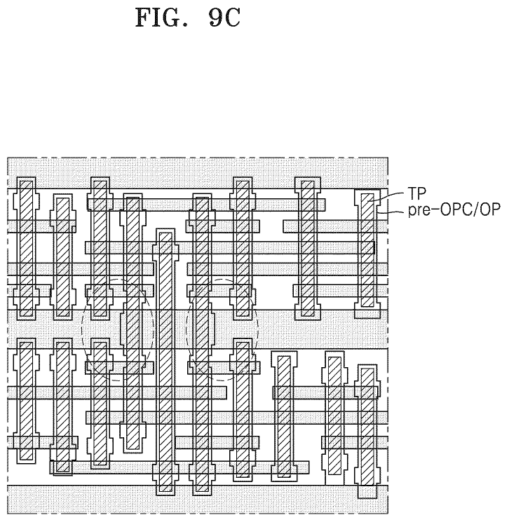

FIGS. 9A through 9C are conceptual diagrams of the design layout of the target pattern, the OPC pattern by using the OPC method of a comparison example, and an OPC pattern by using the OPC method of the present embodiment, respectively.

Referring to FIGS. 9A through 9C, in FIG. 9A, a design layout of the target pattern TP of the line & space shape is illustrated. Particularly, the target pattern TP including line patterns extending in the y direction may correspond to a pattern to be formed on the substrate by using the EUV process.

In an OPC pattern conv-OPC/OP obtained by applying the OPC method of a comparison example to the design layout of the target pattern TP, as illustrated in FIG. 9B, the line-end of the line pattern may have a hammer head shape, and the side lines of the line pattern may have a jog shape formed by small segments. The OPC method of a comparison example may include, for example, the baseline OPC corresponding to the first OPC described above. For reference, in FIG. 9B, the side line of the line pattern is illustrated, for convenience, as one straight line shape, not as a jog shape. When a single patterning process using EUV is performed on the OPC pattern conv-OPC/OP obtained by using the OPC method of the comparison example, a line bridge L/B defect or a pinch-off P/O defect may occur at line-ends of the line patterns adjacent to each other or in other line pattern at the line-ends thereof, which are indicated by dashed lined ellipses.

Alternatively, the OPC pattern pre-OPC/OP obtained by using the OPC method of the present embodiments may, as illustrated in FIG. 9C, have a shape, in which the line-end portions of the line patterns adjacent to each other is thinned, and in addition, a width of the side surface line of other line patterns adjacent to the line-ends is enlarged. Accordingly, even when a single patterning process using EUV is performed on the OPC pattern pre-OPC/OP obtained by using the OPC method of the present embodiments, a line bridge L/B defect or a pinch-off P/O defect may be prevented (and/or mitigated) at line-ends of the line patterns adjacent to each other or in another line pattern at the line-ends thereof, which are indicated by dashed lined ellipses.

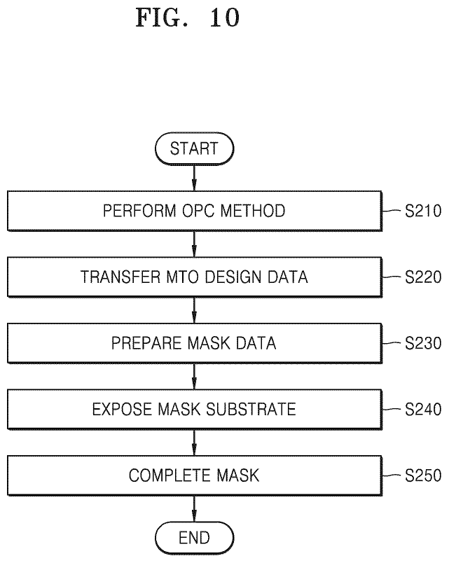

FIG. 10 is a schematic flowchart of a mask manufacturing method including an OPC method, according to at least one embodiment. Descriptions are given with reference to FIGS. 1 through 7B together, and duplicate descriptions already given with reference to FIGS. 1 through 9C are briefly given or omitted.

Referring to FIG. 10, the mask manufacturing method including the OPC method according to at least one embodiment (hereinafter, simply referred to as ‘mask manufacturing method’) may firstly perform the OPC method (S210). The OPC method in an operation of performing the OPC method (S210) may include the OPC method of FIG. 1. The OPC method may include receiving a design layout for a target pattern, obtaining an OPC pattern by performing the first OPC, obtaining a simulation contour, performing the line-end sharpening OPC LES-OPC on line-ends of the line patterns adjacent to each other, cutting portions of the line-ends of the line patterns adjacent to each other, and performing the second OPC OPC2 on the side lines of another line pattern. In addition, performing the line-end sharpening OPC LES-OPC may include defining the reference bridge margin region, defining a bulging bridge margin region, and thinning an OPC pattern portion corresponding to the line-end. Each operation of the OPC method may be the same as each operation of the OPC method of FIG. 1. In addition, each operation included in the operation of performing the line-end sharpening OPC LES-OPC may be the same as each operation included in the operation of performing the line-end sharpening OPC LES-OPC in FIG. 2.

After the OPC method is performed, mask tape-out (MTO) design data is transferred to a mask manufacturing apparatus and/or team (S220). In general, MTO may mean a task of transferring pieces of data of the final design layout obtained by using the OPC method and requesting manufacture of the mask. Thus, in the mask manufacturing method of the present embodiment, the MTO design data may eventually mean the OPCed design layout obtained by using the OPC method, and/or data of the OPCed design layout. The MTO design data may have a graphic data format that is used in electronic design automation (EDA) software, etc.

For example, the MTO design data may have a data format, such as graphic data system II (GDS2) and open artwork system interchange standard (OASIS). In at least some embodiments, the design data may include instructions enabling the manufacture of the mask.

Next, mask data preparation (MDP) is performed (S230). The MDP may include, for example, i) a format conversion known as fracturing, ii) an augmentation of a bar code for mechanical reading, a standard mask pattern for inspection, a job deck, or the like, and iii) verification of automatic and manual methods. In this case, the job deck may mean an operation of generating a text file related to a series of commands, such as arrangement information about multi-mask files, a reference dose, exposure speed, and an exposure method.

The format conversion (e.g., fracturing) may mean a process of dividing the MTO design data into respective regions and changing the MTO design data into a format for an electron beam writer. The fracturing may include, for example, data manipulation, such as scaling, sizing of data, rotation of data, pattern reflection, and color reversal. In a conversion process by using the fracturing, data for various systematic errors occurring somewhere in a process of transferring the design data to an image on a wafer may be corrected.

A data compensation process for the systematic errors may be referred to as a mask process correction (MPC), and may include, for example, line width adjustment called as critical dimension (CD) adjustment, an operation of increasing a pattern arrangement accuracy, etc. Thus, the fracturing may be a process which contributes to improving quality of the final mask, and in addition, is performed in advance for the MPC. In this case, the systematic errors may be caused by distortion occurring in the exposure process, a mask development process, a mask etching process, a wafer imaging process, etc.

In at least some embodiments, the MDP may include the MPC. The MPC may be referred to as a process of correcting an error occurring during the exposure process, as described above (e.g., a process of correcting the systematic error). In these cases, the exposure process may include a concept generally including electron beam writing, developing, etching, baking, etc. In addition, data processing may be performed ahead of the exposure process. The data processing may include a kind of pre-processing process for the mask data, and may include grammar checking, exposure time prediction, or the like of the mask data.

After the mask data is prepared, a mask substrate is exposed based on the mask data (S240). In these cases, the exposure may mean, for example, the electron beam writing. In this case, the electron beam writing may be performed by using a gray writing method using, for example, a multi-beam mask writer (MBMW). In addition, the electron beam writing may also be performed by using a variable shape beam (VSB) writer.

On the other hand, after the MDP is completed, a process of converting the mask data into pixel data may be performed ahead of the exposure process. The pixel data may include data that is directly used for an actual exposure, and may include data on shapes of an object to be exposed and data on a dose allocated to each shape of the object. In this case, the data on shapes may include bit-map data into which shape data, or vector data, has been converted by rasterization or the like.

After the exposure process, a series of processes is performed to complete the mask (S250). The series of processes may include processes of, for example, development, etching, cleaning, etc. In addition, the series of processes of manufacturing a mask may include a measurement process, a defect inspection, and a defect repair process. Furthermore, a series of processes of manufacturing masks may also include a pellicle application process. In this case, when it is verified by final cleaning and inspection processes that there are no contamination particles or chemical stain, the pellicle application process may mean a process of attaching pellicles to a surface of the mask to protect the mask from subsequent contamination during a delivery and a service life of the mask.

In the mask manufacturing method of the inventive concepts, the OPC method may include a process of LES OPC to thin out an OPC pattern of line-end portions of line patterns adjacent to each other in the y direction, a process of cutting a portion of the line-end of each of the line patterns, and a process of performing the second OPC on another line pattern adjacent to line-ends in the x direction. Therefore, the mask manufacturing method of the inventive concepts may ensure sufficient mass production margin for the target pattern having the critical pitch, so that a mask, which implements the target pattern of the critical pitch by using the single exposure patterning, may be manufactured. Particularly, the mask manufacturing method of the inventive concepts may ensure manufacturing of an EUV mask, which is reliable and does not generate pinch-off P/O defects and line bridge L/B defects even when the target pattern having the critical pitch is implemented in the EUV process by using the single exposure patterning.

While the inventive concepts have been particularly shown and described with reference to embodiments thereof, it will be understood that various changes in form and details may be made therein without departing from the spirit and scope of the following claims.

What is claimed is:

1. An optical proximity correction (OPC) method comprising:
receiving a design layout for a target pattern to be formed on a substrate;
obtaining an OPC pattern by performing a first OPC on the design layout;
obtaining a simulation contour of the OPC pattern;
performing, based on the simulation contour, a line-end sharpening (LES) OPC on line-ends of line patterns included in the OPC pattern, the line patterns extending in a first direction and adjacent to each other in the first direction;
cutting a portion of at least one of the line-ends of the line patterns adjacent to each other; and
performing a second OPC on side lines of another line pattern, the another line pattern adjacent to the at least one line-end in a second direction perpendicular to the first direction and extending in the first direction.

2. The OPC method of claim 1, wherein performing the LES OPC comprises:
defining a reference bridge margin region for the at least one line-end based on the simulation contour;
defining a bulging bridge margin region for the at least one line-end based on a line-end bulging resulting from etching; and
thinning another portion of the OPC pattern corresponding to the at least one line-end such that an overlap region, in which the bulging bridge margin region overlaps the other line pattern, is removed.

3. The OPC method of claim 2, wherein
a width Dbul is calculated using Formula 1 below,
Dbul=Rb−Ra, [Formula 1]
the width Dbul corresponding to a width of the overlap region in the second direction,
Ra is a reference radius corresponding to ½ of a width of the line pattern in the second direction,
a radius Rb is a bulging radius corresponding to ½ of a maximum width corresponding to the line-end bulging,
the reference bridge margin region is a region covered by the radius Ra plus a process margin at the at least one line-end, and
the bulging bridge margin region is a region covered by the bulging or the radius Rb plus the process margin at the at least one line-end.

4. The OPC method of claim 3, wherein, the performing of the LES OPC is performed such that, when the radius Rb is changed to a radius Rb′ by changing the line-end bulging, the radius Rb′ satisfies Formula 2 below,
Rc≤Rb′≤Ra, and [Formula 2]
a radius Rc is a minimum radius at the at least one line-end such that a pinch-off does not occur at the line-end portion.

5. The OPC method of claim 2, wherein, in the cutting of a portion of the at least one line-end,
a width Dcut satisfies Formula 3 below,
Dcut=(Scut−S_{LE})/2, [Formula 3]
the width Dcut corresponding to a width of cutting the at least one line-end,
a distance S_{LE} is a distance between line-ends adjacent to each other after the LES OPC is performed, and
a distance Scut is a distance between the adjacent line-ends after the cutting.

6. The OPC method of claim 5, wherein the width Dcut is a width that prevents the bulging bridge margin regions of the adjacent line-ends from overlapping each other.

7. The OPC method of claim 1, wherein,
the second OPC is performed to maximize an increased width Dopc, the increased width Dope corresponding to an increased width of the side line portion of the other line pattern in the second direction,
the increased width Dopc is calculated using Formula 4 below,
Dopc=Wopc−W_{LES}, [Formula 4]
a width Wopc is a width of the side line portion in the second direction after the second OPC, and
a width W_{LES} is a width of the side line portion in the second direction before the second OPC.

8. The OPC method of claim 7, wherein the increased width Dope varies depending on a size of a segment in segment fracturing on the side line of the other line pattern.

9. The OPC method of claim 1, wherein
the first OPC is a baseline OPC, and
the OPC pattern corresponding to the line pattern comprises an end of a hammer head and a side line of a jog shape.

10. The OPC method of claim 1, wherein, when the target pattern uses only the first OPC and comprises a critical line width which would otherwise require two times or more of an extreme ultra-violet (EUV) exposure process, and the target pattern is formed using the EUV exposure process once.

11. An optical proximity correction (OPC) method comprising:
receiving a design layout for a target pattern to be formed on a substrate;
obtaining an OPC pattern by performing a first OPC on the design layout;
obtaining a simulation contour of the OPC pattern;
defining, based on the simulation contour, a reference bridge margin region and a bulging bridge margin region for line-ends of line patterns included in the OPC pattern, the line patterns extending in the first direction and being adjacent to each other in the first direction;
performing a line-end sharpening (LES) OPC on at least one of the line-ends such that an overlap region, in which another line pattern adjacent to the at least one line-end in a second direction perpendicular to the first direction and extending in the first direction overlaps the bulging bridge margin region, is removed;
cutting a portion of the at least one line-end; and
performing a second OPC on a side line of the another line pattern,
wherein, when the target pattern uses only the first OPC and comprises a critical line width which would otherwise require two times or more of an extreme ultra-violet (EUV) exposure process, the target pattern is formed using the EUV exposure process once.

12. The OPC method of claim 11,
a width Dbul is calculated using Formula 1 below,
Dbul=Rb−Ra, [Formula 1]
the width Dbul corresponding to a width of the overlap region in the second direction,
a radius Ra is a reference radius corresponding to ½ of a width of the line pattern in the second direction,
a radius Rb is a bulging radius corresponding to ½ of a maximum width corresponding to the line-end bulging,
the performing of the LES OPC is performed such that when the radius Rb is changed to a radius Rb′ by changing the line-end bulging, the radius Rb′ satisfies Formula 2 below,
wherein Rc≤Rb′≤Ra, and [Formula 2]
a radius Rc is a minimum radius at the at least one line-end such that a pinch-off does not occur at the line-end portion.

13. The OPC method of claim 11, wherein, in the cutting of a portion of the at least one line-end,
a width Dcut satisfies Formula 3 below,
Dcut=(Scut−S_{LE})/2, [Formula 3]
the width Dcut corresponding to a width of cutting the line-end,
a distance S_{LE} is a distance between line-ends adjacent to each other after the LES OPC is performed,
a distance Scut is a distance between the adjacent line-ends after cutting, and
the width Dcut is a width that prevents the bulging bridge margin regions of the adjacent line-ends from overlapping each other.

14. The OPC method of claim 11, wherein, the second OPC is performed to maximize an increased width Dopc, the increased width Dope corresponding to an increased width of the side line portion of the other line pattern in the second direction,
the increased width Dopc is calculated using Formula 4 below,
Dopc=Wopc−W_{LES}, [Formula 4]
a width Wopc is a width of the side line portion in the second direction after the second OPC, and
a width W_{LES} is a width of the side line portion in the second direction before the second OPC.

15. A mask manufacturing method comprising:
performing an optical proximity correction (OPC) method such that an OPCed design layout is obtained, the OPCed design corresponding to a target pattern to be formed on a substrate;
preparing mask tape-out (MTO) design data, the MTO design data based on the OPCed design layout data;
preparing mask data based on the MTO design data; and
performing exposure onto a mask substrate based on the mask data,
wherein the performing of the OPC method comprises
receiving a design layout for a target pattern to be formed on a substrate,
obtaining an OPC pattern by performing a first OPC on the design layout,
obtaining a simulation contour of the OPC pattern,
performing, based on the simulation contour, a line-end sharpening (LES) OPC on line-ends of line patterns included in the OPC pattern, the line patterns extending in a first direction and adjacent to each other in the first direction, cutting a portion of at least one of the line-ends, and
performing a second OPC on side lines of another line pattern, the another line pattern adjacent to the at least one line-end in a second direction perpendicular to the first direction and extending in the first direction.

16. The method of claim 15, wherein performing the LES OPC comprises:
defining a reference bridge margin region for the at least one line-end based on the simulation contour;
defining a bulging bridge margin region for the at least one line-end based on a line-end bulging resulting from etching; and
thinning another portion of the OPC pattern corresponding to the at least one line-end such that an overlap region, in which the bulging bridge margin region overlaps the other line pattern, is removed.

17. The method of claim 16, wherein
a width Dbul is calculated using Formula 1 below,
Dbul=Rb−Ra, [Formula 1]
the width Dbul corresponding to a width of the overlap region in the second direction,
a radius Ra is a reference radius corresponding to ½ of a width of the line pattern in the second direction,
a radius Rb is a bulging radius corresponding to ½ of a maximum width corresponding to the line-end bulging,
the performing of the LES OPC is performed such that when the radius Rb is changed to a radius Rb′ by changing the line-end bulging, the radius Rb′ satisfies Formula 2 below,
Rc≤Rb′≤Ra, and [Formula 2]
a radius Rc is a minimum radius at the at least one line-end such that a pinch-off does not occur at the line-end portion.

18. The method of claim 16, wherein, in the cutting of a portion of the at least one line-end,
a width Dcut satisfies Formula 3 below,
Dcut=(Scut−S_{LE})/2, [Formula 3]
the width Dcut corresponding to a width of cutting the at least one line-end,
a distance S_{LE} is a distance between line-ends adjacent to each other after the LES OPC is performed,
a distance Scut is a distance between the adjacent line-ends after cutting, and
the width Dcut is a width that prevents the bulging bridge margin regions of the adjacent line-ends from overlapping each other.

19. The method of claim 15, wherein, the second OPC is performed to maximize an increased width Dopc, the increased width Dope corresponding to an increased width of the side line portion of the other line pattern in the second direction,
the increased width Dopc is calculated using Formula 4 below,
Dopc=Wopc−W_{LES}, [Formula 4]
a width Wopc is a width of the side line portion in the second direction after the second OPC, and
a width W_{LES} is a width of the side line portion in the second direction before the second OPC.

20. The method of claim 15, further comprising: manufacturing mask to form the target pattern based on a result of the second OPC,
wherein, when the target pattern uses only the first OPC and comprises a line width which would otherwise require two times or more of an extreme ultra-violet (EUV) exposure process, and the mask is manufactured using the EUV exposure process once.
